(19) United States
(12) Patent Application Publication
(10) Pub. No.: US 2017/0133592 A1
(43) Pub. Date: May 11, 2017

(54) MASK FRAME ASSEMBLY, DEVICE FOR DEPOSITION INCLUDING THE SAME, AND METHOD OF MANUFACTURING DISPLAY DEVICE

(71) Applicant: Samsung Display Co., Ltd., Yongin-si (KR)

(72) Inventor: Deawon BAEK, Yongin-si (KR)

(21) Appl. No.: 15/178,071

(22) Filed: Jun. 9, 2016

(30) Foreign Application Priority Data
Nov. 6, 2015 (KR) 10-2015-0155790

(51) Int. Cl. H01L 51/00; C23C 16/04; H01L 51/56

(52) U.S. Cl. CPC H01L 51/0011; H01L 51/56; C23C 16/042; H01L 51/5012

(57) ABSTRACT

A mask frame assembly a frame including an opening, a mask including a pattern unit, the pattern unit including pattern holes through which a deposition material is configured to pass, and a support stick disposed between the mask and a vapor deposition source and crossing a portion of the opening, the support stick including an opening hole exposing at least a portion of the pattern unit, in which first and second ends of the mask are coupled to the frame, and at least a portion of the support stick is coupled to the mask.

### CROSS-REFERENCE TO RELATED APPLICATION

This application claims priority from and the benefit of Korean Patent Application No. 10-2015-155790, filed on Nov. 6, 2015, which is hereby incorporated by reference for all purposes as if fully set forth herein.

### BACKGROUND

Field

Exemplary embodiments relate to a mask frame assembly. More particularly, exemplary embodiments relate to a device for deposition including the same, and a method of manufacturing a display device.

Discussion of the Background

Mobility-based electronic devices have a wide range of uses. A tablet personal computer (PC) may be used as a mobile electronic device, in addition to a small electronic device such as a mobile phone. The mobile electronic device may include a display unit for providing visual information to users, such as images or moving images, in order to support various functions.

As the size of components for driving the display unit may be reduced, the size of a display unit that occupies an electronic device may be increased. Recently, a display unit that may be bent to have a predetermined angle from a flat state has been developed.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a mask frame assembly, a device for deposition including the same, and a method of manufacturing a display device.

Additional aspects will be set forth in the detailed description which follows, and, in part, will be apparent from the disclosure, or may be learned by practice of the inventive concept.

An exemplary embodiment discloses a mask frame assembly including a frame including an opening, a mask including a pattern unit, the pattern unit including pattern holes through which a deposition material is configured to pass, and a support stick disposed between the mask and a vapor deposition source and crossing a portion of the opening, the support stick including an opening hole exposing at least a portion of the pattern unit, in which first and second ends of the mask are coupled to the frame, and at least a portion of the support stick is coupled to the mask.

An exemplary embodiment also discloses a deposition device including a vapor deposition source configured to supply a deposition material to a substrate, and a mask frame assembly disposed between the vapor deposition source and the substrate, the mask frame assembly configured to pass the deposition material therethrough. The mask frame assembly includes a frame including an opening, a mask including a pattern unit, the pattern unit including pattern holes through which the deposition material is configured to pass, and a support stick disposed between the mask and the vapor deposition source and crossing a portion of the opening, the support stick including an opening hole exposing at least a portion of the pattern unit, in which first and second ends of the mask are coupled to the frame, and at least a part of the support stick is coupled to the mask.

An exemplary embodiment further discloses a method of manufacturing a display device including forming an organic layer or a first electrode on a substrate by using a mask frame assembly. The mask frame assembly includes a frame including an opening, a mask including a pattern unit, the pattern unit including pattern holes through which a deposition material is configured to pass, and a support stick disposed between the mask and a vapor deposition source and crossing a portion of the opening, the support stick including an opening hole exposing at least a portion of the pattern unit, in which first and second ends of the mask are coupled to the frame, and at least a part of the support stick is coupled to the mask.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic perspective view of a mask frame assembly according to an exemplary embodiment.

FIG. 2 is a schematic plan view of the mask frame assembly of FIG. 1.

FIG. 3 is a cross-sectional view of the mask frame assembly of FIG. 2.

FIG. 4 is a schematic plan view of a mask frame assembly according to an exemplary embodiment.

FIG. 5 is a schematic plan view of a mask frame assembly according to an exemplary embodiment.

FIG. 6 is a schematic plan view of a mask frame assembly according to an exemplary embodiment.

FIG. 7 is a cross-sectional view of the mask frame assembly of FIG. 6.

FIG. 8 is a plan view of a support stick according to an exemplary embodiment.

FIG. 9 is a plan view of a support stick according to an exemplary embodiment.

FIG. 10 is a plan view of a support stick according to an exemplary embodiment.

FIG. 11 is a schematic conceptual diagram of a deposition device including the mask frame assembly of FIG. 1.

FIG. 12 is a cross-sectional view of one sub-pixel of an organic light-emitting display device (OLED) with a light-emitting layer deposited onto a display substrate by using the deposition device of FIG. 11.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

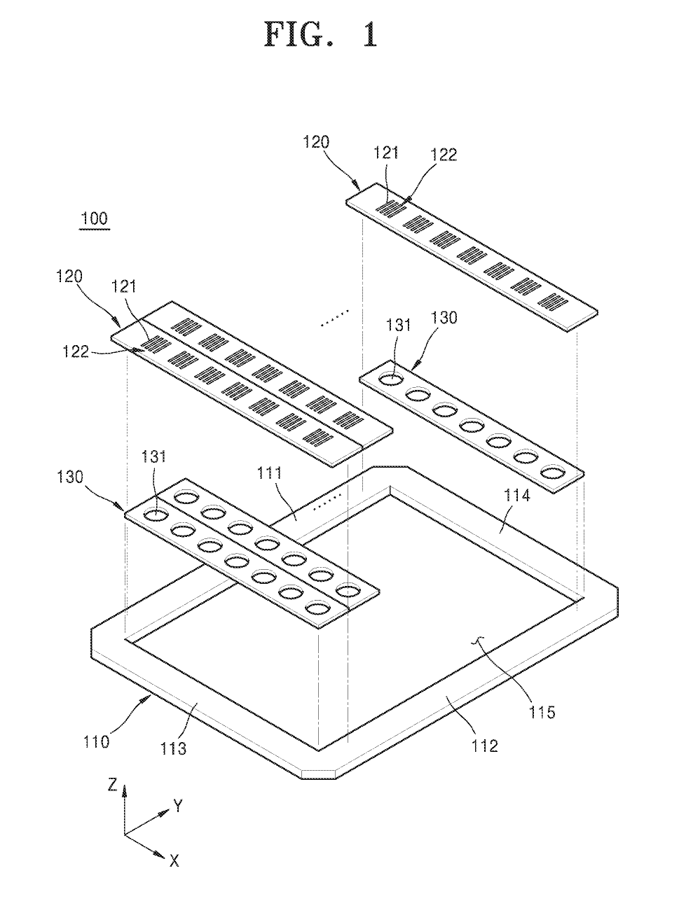

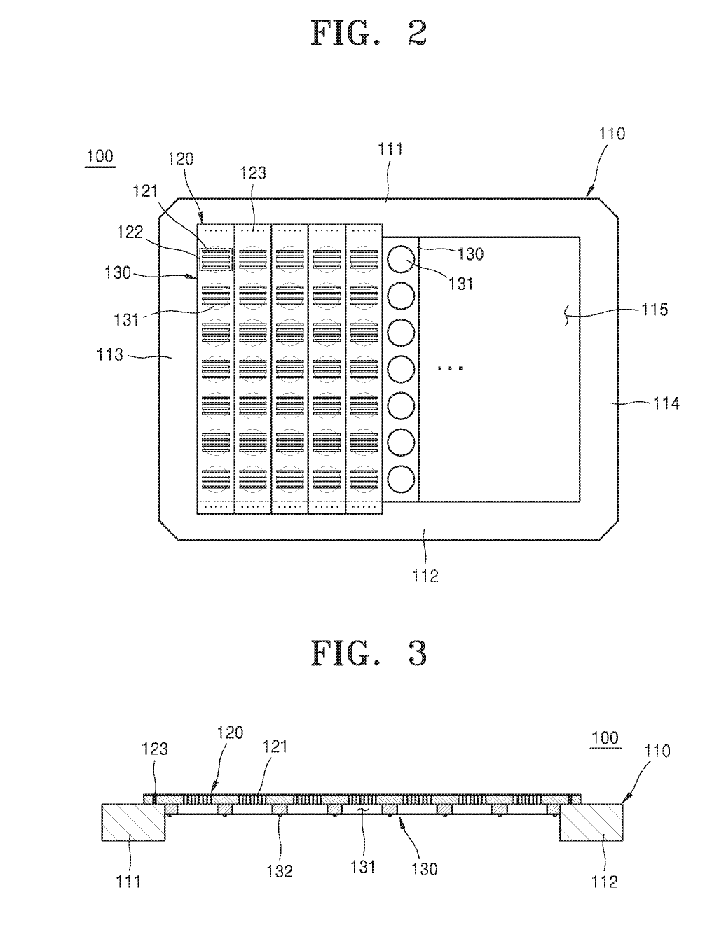

FIG. 1 is a schematic perspective view of a mask frame assembly 100 according to an exemplary embodiment. FIG. 2 is a schematic plan view of the mask frame assembly 100 of FIG. 1. FIG. 3 is a cross-sectional view of the mask frame assembly 100 of FIG. 2.

Referring to FIGS. 1 to 3, the mask frame assembly 100 may include a frame 110, a mask 120, and a support stick 130.

The frame 110 may include an opening 115 and frames 111, 112, 113, and 114 surrounding the opening 115. A first frame 111, a second frame 112, a third frame 113, and a fourth frame 114 may be connected with each other. The first frame 111 and the second frame 112 may face each other in an x-axis direction and extend along a y-axis direction. The third frame 113 and the fourth frame 114 may face each other in the y-axis direction and extend along the x-axis direction.

The first frame 111, the second frame 112, the third frame 113, and the fourth frame 114 may be connected with each other, to form the frame 110 in a rectangular frame shape. The frame 110 may include a material that may have little deformation during welding of the mask 120, such as a metal with high rigidity.

The mask 120 may be arranged on the frame 110. The mask 120 may include a pattern unit 122 having pattern holes 121 therein, through which a deposition material passes. The pattern unit 122 may have a square shape, however, the shape of the pattern unit 122 may vary. Hereinafter, for convenience of description, the pattern unit 122 will be described as to having a square shape.

In general, forming a precise deposition pattern may include enhancing adhesion between the mask 120 and a substrate (not illustrated) arranged on the mask 120, and reducing a shadow effect. The mask 120 may be manufactured by using a thin plate. The mask 120 may include stainless steel, Invar, nickel (Ni), cobalt (Co), a nickel alloy, a Ni—Co alloy, etc.

Masks 120, which may be separated from each other, may be disposed along the y-axis direction, to prevent a droop phenomenon from the weight thereof. In other words, masks 120 may be arranged along a long side of the frame 110, that is, along the first and second frames 111 and 112 having relatively longer lengths. Each mask 120 may have a stick shape. The mask 120 may alternatively have various shapes, when a width of the mask 120 is shorter than a length thereof in an extension direction.

The masks 120 may be separated from each other in a direction (e.g., the y-axis) crossing the extension direction (e.g., the x-axis). In more detail, the masks 120 may be repeatedly arranged between the third frame 113 and the fourth frame 114, and both ends of each of the masks 120 may be welded and fixed onto the first frame 111 and the second frame 112. The first and second frames 111 and 112 and both ends of each of the masks 120 may be coupled to each other via a first welding portion 123. In this manner, the masks 120 may cover the opening 115.

Each mask 120 may be a thin film having magnetic properties, and may include nickel or a nickel alloy. For example, the mask 120 may include a Ni—Co alloy, on which a fine pattern may be easily formed and has an excellent surface roughness.

The mask 120 may be manufactured by using an etching method, by forming a photoresist layer having a pattern identical to each pattern hole 121 on the thin film, or by etching the thin film after a film having the pattern of the pattern hole 121 has been attached to the thin film. Furthermore, the mask 120 may be manufactured via electro-forming or electroless plating. According to an exemplary embodiment, the pattern unit 122 may include a mask pattern having an overall open state or a mask pattern having a stripe shape.

The support stick 130 may include an opening hole 131 exposing at least a portion of the pattern unit 122. The support sticks 130 may cover the opening 115. In more detail, the support sticks 130 may be arranged along a long side of the frame 110, that is, along the first and second frames 111 and 112.

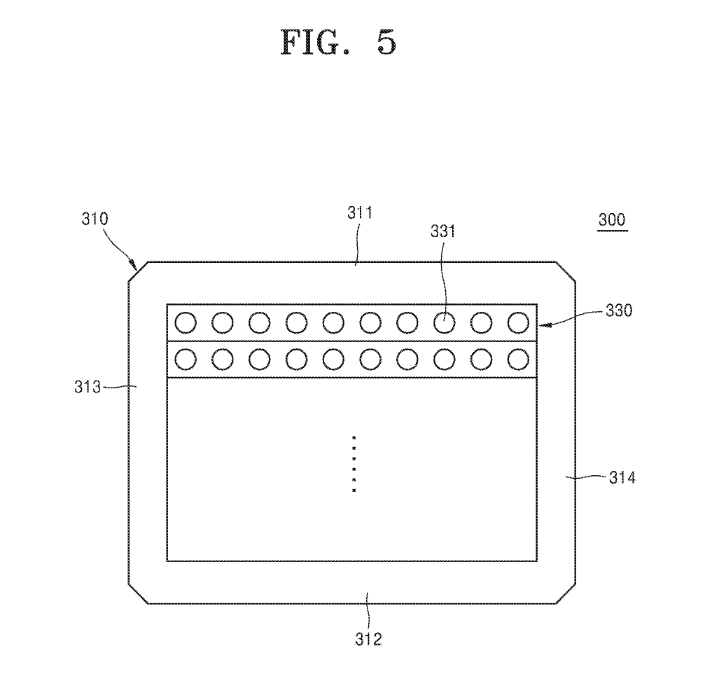

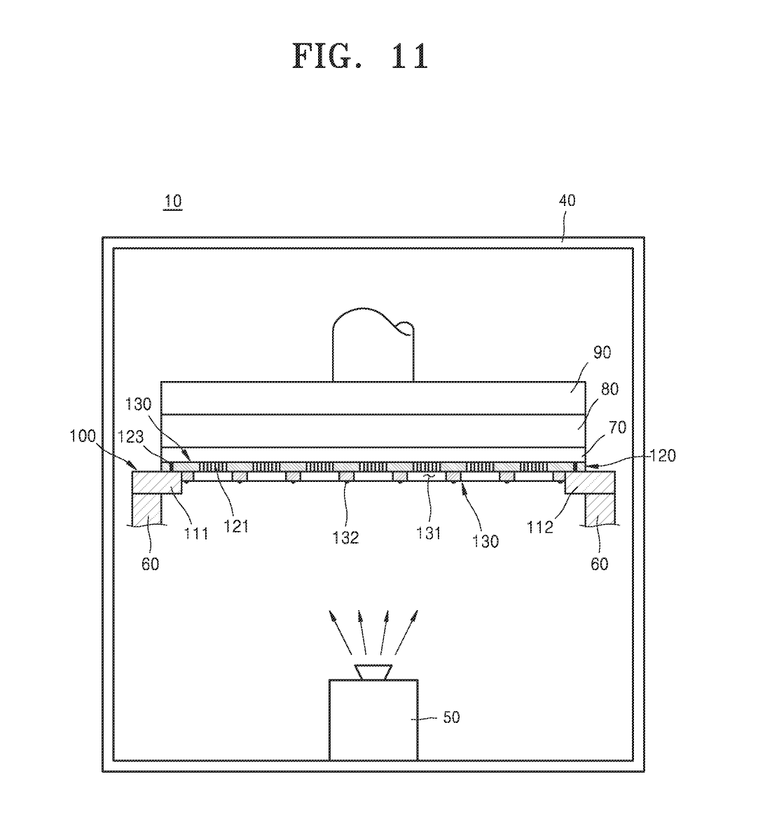

The support stick 130 may be arranged between the mask 120 and a vapor deposition source 50 (of FIG. 11) for injecting a deposition material onto a substrate 70 (of FIG. 11). More particularly, the support stick 130 may be coupled to a surface of the mask 120 via a second welding portion 132. FIGS. 1 to 3 illustrate that an entire surface of the support stick 130 is coupled to the mask 120 overlapping each other, and FIG. 5 illustrates that a portion of a surface of the support stick 130 is coupled to the mask 120 overlapping each other.

The opening hole 131 may have a circular shape, as illustrated in FIGS. 1 to 3. A deposition material may pass through a region in which the opening hole 131 and the pattern unit 122 are superimposed, while being blocked in a region adjacent to the opening hole 131 by the pattern unit 122 that overlaps the support stick 130.

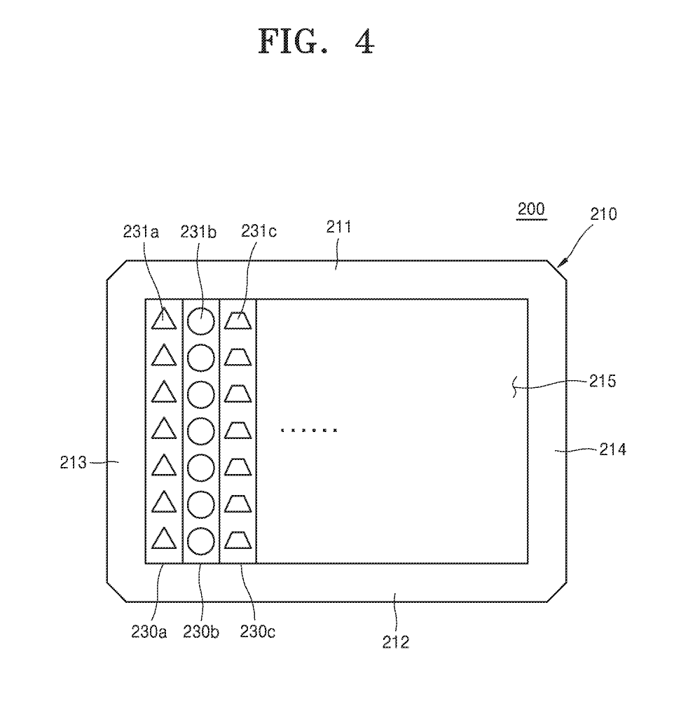

FIG. 4 is a schematic plan view of a mask frame assembly 200 according to an exemplary embodiment.

Referring to FIG. 4, the mask frame assembly 200 may include a frame 210, a mask (not illustrated), and support sticks 230a, 230b, and 230c. The frame 210 may include an opening 215 and frames 211, 212, 213, and 214 surrounding the opening 215. Configurations and constituent elements of the mask frame assembly 200 may be substantially similar to those of the mask frame assembly illustrated with reference to FIGS. 1 to 3, and thus, repeated description thereof will be omitted.

The shapes of opening holes 231a, 231b, and 231c may be different from each other. More particularly, the opening hole 231a may have a triangular shape, the opening hole 231b may have a circular shape, and the opening hole 231c may have a parallelogram shape. Each of the opening holes 231a, 231b, and 231c may have at least one of a circular shape, an oval shape, and a polygonal shape.

FIG. 5 is a schematic plan view of a mask frame assembly 300 according to an exemplary embodiment.

Referring to FIG. 5, a support stick 330 may be arranged in plural along a short side of a frame 310, that is, along third and fourth frames 313 and 314. As compared to the support sticks 130 and 230 of FIGS. 2 and 4, the support stick 330 may extend in a direction crossing a direction in which the support sticks 130 and 230 cross the openings 115 and 215, respectively. In this manner, both ends of the support stick 330 may be coupled to the third and fourth frames 313 and 314, respectively. The support stick 330 may include an opening hole 331.

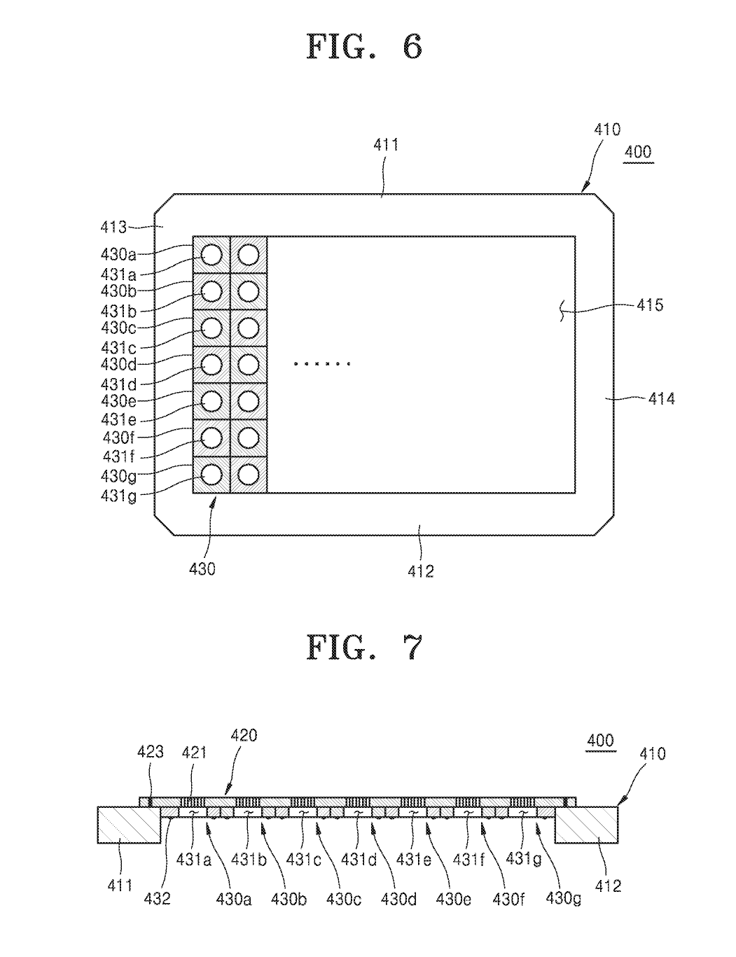

FIG. 6 is a schematic plan view of a mask frame assembly 400 according to an exemplary embodiment. FIG. 7 is a cross-sectional view of the mask frame assembly 400 of FIG. 6.

Support sticks 430a, 430b, 430c, 430d, 430e, 430f, and 430g of FIG. 6 may be formed along a long side of a frame 410, that is, along first and second frames 411 and 412. The support sticks 430a to 430g may also be formed along a short side of the frame 410, that is, along third and fourth frames 413 and 414.

The support sticks 430a to 430g formed along the first and second frames 411 and 412 of the frame 410, and along the third and fourth frames 413 and 414, may be separated from each other. In this manner, the support sticks 430a to 430g may be respectively correspond to a pattern unit (not shown) and block at least a portion of the corresponding pattern unit.

Referring to FIG. 7, first and second frames 411 and 412 and the both ends of each of the masks 420 may be coupled to each other via a first welding portion 423. The support sticks 430a to 430g may be coupled to a surface of the mask 420 via a second welding portion 432.

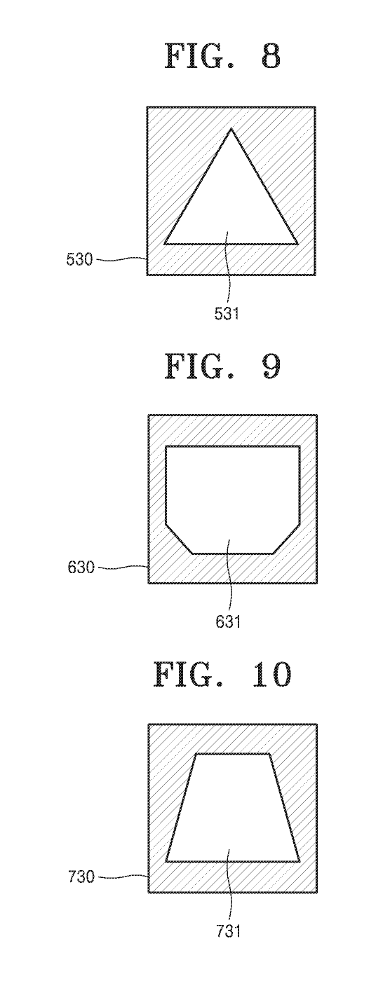

FIG. 8 is a plan view of a support stick 530 according to an exemplary embodiment. FIG. 9 is a plan view of a support stick 630 according to an exemplary embodiment. FIG. 10 is a plan view of a support stick 730 according to an exemplary embodiment.

Referring to FIGS. 6 to 10, when the support sticks 430a to 430g that may be separated from each other along the long and short sides of the frame 410 respectively have opening holes 431a, 431b, 431c, 431d, 431e, 431f, and 431g, the shapes of opening holes 531, 631, and 731 may vary, as illustrated in FIG. 4.

The opening hole 531 may have a triangular shape as illustrated in FIG. 8, the opening hole 631 may have a hexagonal shape as illustrated in FIG. 9, and the opening hole 731 may have a parallelogram shape as illustrated in FIG. 10. The opening holes 531, 631, and 731 may alternatively have a circular shape having a cut-off portion (not shown). The shapes of the opening holes 531, 631, and 731 may vary.

FIG. 11 is a schematic conceptual diagram of a deposition device 10 including the mask frame assembly 100 of FIG. 1.

Referring to FIG. 11, the deposition device 10 may include a vapor deposition source 50 for supplying a deposition material to a substrate 70 in a chamber 40, the mask frame assembly 100 on one surface of the substrate 70 facing the vapor deposition source 50, and a magnet plate 90 on the other surface of the substrate 70, which is opposite to the surface of the substrate 70 facing the vapor deposition source 50, in which the mask frame assembly 100 is adhered to the substrate 70 by a magnetic force.

The deposition device 10 may further include a pressing plate 80 interposed between the substrate 70 and the magnet plate 90, which may press the substrate 70 by a magnetic force. The pressing plate 80 may improve adhesion of the substrate 70 and the mask frame assembly 100, before the magnet plate 90 moves to the substrate 70 and presses the mask frame assembly 100 with a magnetic force.

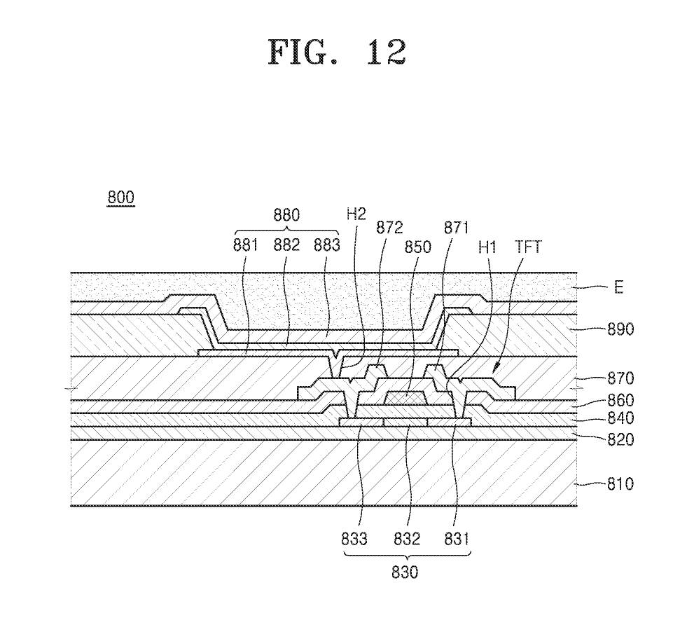

FIG. 12 is a cross-sectional view of one sub-pixel of an organic light-emitting display device (OLED) 800 with a light-emitting layer deposited onto a display substrate by using the deposition device 10 of FIG. 11. The OLED 800 may be manufactured by the deposition device 10 including the mask frame assembly 100.

Referring to FIG. 12, the OLED 800 may include a substrate 810 and a display unit (not shown). The OLED 800 may further include a thin-film encapsulation film “E” or an encapsulation substrate (not shown) disposed on the display unit. The encapsulation substrate may be the same as or substantially similar to that used in a general display device, and thus, a detailed description thereof will be omitted. Hereinafter, the OLED 800 will be described as to including the thin-film encapsulation layer E.

The display unit may be disposed on the substrate 810. The display unit may include a thin-film transistor TFT, a passivation film 870 disposed to cover the thin-film transistor TFT, and an organic light-emitting element 880 disposed on the passivation film 870.

The substrate 810 may be formed of a glass material. Alternatively, the substrate 810 may be formed of a plastic material, or a metal material, such as steel use stainless (SUS) or titanium (Ti). The substrate 810 may include polyimide (PI). Hereinafter, the substrate 810 will be described as to including the glass material.

A buffer layer 820 including an organic compound and/or an inorganic compound (e.g., SiOₓ or SiNₓ) may be disposed on a top surface of the substrate 810. After an active layer 830 having a pattern is disposed on the buffer layer 820. The active layer 830 may be covered by a gate insulating layer 840. The active layer 830 may include a source region 831, a drain region 833, and a channel region 832 disposed between the source region 831 and the drain region 833.

The active layer 830 may include various materials. For example, the active layer 830 may include an inorganic semiconductor material, such as amorphous silicon or crystalline silicon. Alternatively, the active layer 830 may include an oxide semiconductor or an organic semiconductor material. Hereinafter, the active layer 830 will be described as to including amorphous silicon.

The active layer 830 may be formed by forming an amorphous silicon film on the buffer layer 820, crystallizing the amorphous silicon film into a polycrystalline silicon film, and patterning the polycrystalline silicon film. The source region 831 and the drain region 833 of the active layer 830 may be doped with impurities according to a type of the thin-film transistor TFT, such as a driving TFT (not shown) or a switching TFT (not shown).

A gate electrode 850 that corresponds to the active layer 830 and an interlayer insulating layer 860 that covers the gate electrode 850 may be disposed on a top surface of the gate insulating layer 840. After a contact hole H1 is formed in the interlayer insulating layer 860 and the gate insulating layer 840, a source electrode 871 and a drain electrode 872 may be formed on the interlayer insulating layer 860 to respectively contact the source region 831 and the drain region 833.

The passivation film 870 may be disposed on the thin-film transistor TFT. A pixel electrode 881 of the OLED 800 may be disposed on the passivation film 870. The pixel electrode 881 may contact the drain electrode 872 of the thin-film transistor TFT through a via hole H2 formed in the passivation film 870. The passivation film 870 may include an inorganic material and/or an organic material and may have a single-layer structure or a multi-layer structure. The passivation film 870 may be formed as a planarization film having a flat top surface, or the top surface thereof may be curved along the curved shape of a lower film on which the passivation film 870 is disposed. The passivation film 870 may be formed as a transparent insulator, to achieve a resonance effect.

After the pixel electrode 881 is formed on the passivation film 870, a pixel-defining film 890 including an organic material and/or an inorganic material may be formed to cover the pixel electrode 881 and the passivation film 870, and to expose the pixel electrode 881 therethrough.

An intermediate layer 882 and a counter electrode 883 may be disposed on at least the pixel electrode 881. The pixel electrode 881 may be an anode and the counter electrode 883 may be a cathode. Polarities of the pixel electrode 881 and the counter electrode 883 may be switched.

The pixel electrode 881 and the counter electrode 883 may be insulated from each other by the intermediate layer 882, and apply voltages having different polarities to the intermediate layer 882, such that an organic emission layer emits light. The intermediate layer 882 may include an organic emission layer. For example, the intermediate layer 882 may include the organic emission layer and at least one selected from a hole injection layer (HIL), a hole transport layer (HTL), an electron transport layer (ETL), and an electron injection layer (EIL).

A unit pixel P may include sub pixels R, G, and B, and the sub pixels R, G, and B may emit various colors of light. For example, the unit pixel P may include sub pixels R, G, and B emitting red, green and blue lights, and may also include sub pixels emitting red, green, blue, and white lights (not shown), respectively.

The thin-film encapsulation layer E may include inorganic layers, or an inorganic layer and an organic layer. The organic layer of the thin-film encapsulation layer E may include a polymer, and may be a single layer or stacked layers including one of polyethylene terephthalate, polyimide, polycarbonate, epoxy, polyethylene, and polyacrylate. More specifically, the organic layer may be formed of polyacrylate, and include a polymerization of a monomer composition including a diacrylate-based monomer and a triacrylate-based monomer. A monoacrylate-based monomer may be further included in the monomer composition. A photo-initiator, such as a TPO, may be further included in the monomer composition.

The inorganic layer of the thin-film encapsulation layer E may be a single layer or stacked layers including a metal oxide or a metal nitride. More particularly, the inorganic layer may include one of silicon nitride (SiNₓ), aluminum oxide (Al₂O₃), silicon oxide (SiO₂), and titanium oxide (TiO₂). An uppermost layer of the thin-film encapsulation layer E exposed to the outside may be an inorganic layer, which may prevent moisture from penetrating into the OLED 800.

The thin-film encapsulation layer E may have at least one sandwich structure, in which at least one organic layer is disposed between at least two inorganic layers. As another example, the thin-film encapsulation layer E may include at least one sandwich structure, in which at least one inorganic layer is disposed between at least two organic layers. As another example, the thin-film encapsulation layer E may include a sandwich structure, in which at least one organic layer is inserted between at least two inorganic layers and at least one inorganic layer is inserted between at least two organic layers.

The thin-film encapsulation layer E may sequentially include a first inorganic layer, a first organic layer, and a second inorganic layer from a top portion of the OLED 800. As another example, the thin-film encapsulation layer E may sequentially include a first inorganic layer, a first organic layer, a second inorganic layer, a second organic layer, and a third inorganic layer from the top portion of the OLED 800. As another example, the thin-film encapsulation layer E may sequentially include a first inorganic layer, a first organic layer, a second inorganic layer, a second organic layer, a third inorganic layer, and a third organic layer from the top portion of the OLED 800.

A halogenized metal layer including lithium fluoride (LiF) may be additionally included between the OLED 800 and the first inorganic layer. The halogenized metal layer may prevent the OLED 800 form being damaged, when the first inorganic layer is formed using sputtering. An area of the first organic layer may be smaller than an area of the second inorganic layer. The area of the second inorganic layer may be smaller than an area of the third inorganic layer.

According to the exemplary embodiments of the present invention, when a defect occurs in a pattern hole of a mask, a support stick corresponding to the position of the pattern hole having the defect may be replaced, which may reduce the time and costs associated with manufacturing and repairing a mask frame assembly.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

1. A mask frame assembly, comprising:
a frame comprising an opening;
a mask comprising a pattern unit, the pattern unit comprising pattern holes through which a deposition material is configured to pass; and
a support stick disposed between the mask and a vapor deposition source and crossing a portion of the opening, the support stick comprising an opening hole exposing at least a portion of the pattern unit,
wherein:
first and second ends of the mask are coupled to the frame;
at least a portion of the support stick is coupled to the mask; and
the pattern unit and the opening hole have different shapes.

2. The mask frame assembly of claim 1, wherein the mask is disposed in plural along a long side of the frame.

3. The mask frame assembly of claim 1, wherein the opening hole has at least one of a circular shape, an oval shape, and a polygonal shape.

4. The mask frame assembly of claim 1, wherein the support stick is disposed in plural along a long side of the frame.

5. The mask frame assembly of claim 1, wherein the support stick is disposed in plural along a short side of the frame.

6. The mask frame assembly of claim 1, wherein the support stick is disposed in plural along long and short sides of the frame.

7. The mask frame assembly of claim 1, further comprising:
a first welding portion coupling the first and second ends of the mask to the frame.

8. The mask frame assembly of claim 1, further comprising:
a second welding portion coupling the support stick to the mask.

9. The mask frame assembly of claim 3, wherein:
the support stick is disposed in plural along a long side of the frame; and
opening holes of adjacent support sticks have different shapes from each other.

10. A deposition device, comprising:
a vapor deposition source configured to supply a deposition material to a substrate; and
a mask frame assembly disposed between the vapor deposition source and the substrate, the mask frame assembly configured to pass the deposition material therethrough, the mask frame assembly comprising:
a frame comprising an opening;
a mask comprising a pattern unit, the pattern unit comprising pattern holes through which the deposition material is configured to pass; and
a support stick disposed between the mask and the vapor deposition source and crossing a portion of the opening, the support stick comprising an opening hole exposing at least a portion of the pattern unit,
wherein:
first and second ends of the mask are coupled to the frame;
at least a part of the support stick is coupled to the mask; and
the pattern unit and the opening hole have different shapes.

11. The deposition device of claim 10, wherein the mask is disposed in plural along a long side of the frame.

12. The deposition device of claim 10, wherein the opening hole has at least one of a circular shape, an oval shape, and a polygonal shape.

13. The deposition device of claim 10, wherein the support stick is disposed in plural along a long side of the frame.

14. The deposition device of claim 10, wherein the support stick is disposed in plural along a short side of the frame.

15. The deposition device of claim 10, wherein the support stick is disposed in plural along long and short sides of the frame.

16. The deposition device of claim 10, further comprising:
a first welding portion coupling the first and second ends of the mask to the frame.

17. The deposition device of claim 10, further comprising:
a second welding portion coupling the support stick to the mask.

18. The deposition device of claim 12, wherein:
the support stick is disposed in plural along a long side of the frame; and
opening holes of adjacent support sticks have different shapes from each other.

19. A method of manufacturing a display device, the method comprising:
forming an organic layer or a first electrode on a substrate by using a mask frame assembly, the mask frame assembly comprising:
a frame comprising an opening;
a mask comprising a pattern unit, the pattern unit comprising pattern holes through which a deposition material is configured to pass; and
a support stick disposed between the mask and a vapor deposition source and crossing a portion of the opening, the support stick comprising an opening hole exposing at least a portion of the pattern unit,
wherein:
first and second ends of the mask are coupled to the frame;
at least a part of the support stick is coupled to the mask; and
the pattern unit and the opening hole have different shapes.

20. The mask frame assembly of claim 1, wherein a length of the mask is greater than a length of the support stick along a short side of the frame.
